(19) United States
(12) Patent Application Publication
(10) Pub. No.: US 2017/0330780 A1
(43) Pub. Date: Nov. 16, 2017

(54) METHOD AND DEVICE FOR TREATING THE UNDERSIDE OF A SUBSTRATE

(71) Applicant: RENA Technologies GmbH, Gütenbach (DE)

(72) Inventors: Kartin WEISE, Freiburg (DE); Bernd-Uwe SANDER, Freiburg (DE); Steffen QUEISSER, Willstaett (DE); Patrick GANTER, Furtwangen (DE); Stephan Alexis PEDIADITAKIS, Heuweiler (DE)

(21) Appl. No.: 15/529,791

(22) PCT Filed: Nov. 24, 2015
(86) PCT No.: PCT/DE2015/100502

§ 371 Date: May 25, 2017

(30) Foreign Application Priority Data
Nov. 25, 2014 (DE) 10 2014 117 276.0

(51) Int. Cl. H01L 21/677; H01L 21/67; H01L 21/306

(52) U.S. Cl. CPC H01L 21/67706; H01L 21/6776; H01L 21/306; H01L 21/67057; H01L 21/67086

(57) ABSTRACT

A method for treating the underside of a planar substrate with a treatment medium includes hydrophobizing the underside of the substrate, subsequently forming a protective liquid film on a top side of the substrate and then bringing the treatment medium into contact with the underside of the substrate. In the process, the protective liquid film protects the upper side of the substrate from any action or effect of the treatment medium and/or outgassing. A device for carrying out the method is also provided.

The invention relates to a method for treating the underside of a planar substrate, and to a device for carrying out the method according to the preamble of claim 12.

Among other things, it is sometimes necessary, in the field of the production of semiconductor components, to treat one side of planar substrates. Frequently, an underside of the substrate is treated for this purpose. Depending on the application case, it may be necessary here to protect the top side of the substrate from any action of the treatment medium used or any harmful outgassings out of the treatment medium. For example, semiconductor components can be damaged by such action on the top side.

WO 2011/047894 A1 discloses, in order to protect the top side of the substrate, spraying or dripping a protective liquid onto the top side or applying it by means of surge pipes. In order that the protective liquid does not pass into the treatment medium, usually a treatment liquid, the protective liquid can be applied to the top side before the underside of the substrate is wetted with the treatment liquid. In this way, the quantity of protective liquid introduced into the treatment liquid can be reduced. However, as already set out in WO 2011/047894 A1, it is even then not possible to prevent protective liquid from dripping off into the treatment medium, or into the treatment liquid. If water is used as the protective liquid, this results in dilution of the treatment liquid and thus increased use of chemicals. Furthermore, increased procedural effort is required in order to ensure constant treatment conditions, for example a constant composition of the treatment liquid, and thus process reliability. If a different material is used as the treatment liquid, this generally results in contamination of the treatment medium with similar results that usually take even more effort to control.

Furthermore, at those locations at which drops of protective liquid run off the top side over edges of the substrate and drip down, streaking can occur during the treatment with the treatment medium. This is attributable to the fact that the underside of the substrate is etched to a lesser degree at these locations. This problem occurs in particular when an etching solution is used as the treatment medium, by means of which a comparatively large amount of material is removed from the underside of the substrate. Such a high degree of etching on one side is required in particular in the case of new silicon solar cell production methods, for example in methods for producing solar cells with a passivated emitter and passivated rear contacts, known as PERC solar cells. The outlined irregularities during etching result in an inhomogeneous appearance of the underside of the substrate and thus, in addition to possible electrical impairments of the semiconductor component, in an inhomogeneous appearance of the finished solar cell. Moreover, problems can arise in subsequent process steps. Thus, for example, an inhomogeneous thickness of an oxide layer arranged on the underside of the substrate can result in an etching step carried out subsequently on the underside of the substrate starting at different times.

Furthermore, in the known procedure, there is the risk of a treatment liquid that is used as the treatment medium and wets the underside of the substrate creeping over the edges of the substrate as a result of a concentration gradient or on account of wetting phenomena and in this way passing onto the top side of the substrate. There, it can locally or extensively damage the surface of the substrate, for example as a result of an etching effect.

Against this background, the present invention is based on the object of providing a method for treating the underside of a planar substrate, by means of which at least some of the outlined disadvantages can be overcome in a favorable manner in terms of effort.

This object is achieved by a method having the features of claim 1.

Furthermore, the present invention is based on the object of providing a device by means of which this method can be carried out and the risk of damage to the top side of the substrate can be reduced further.

This object is achieved by a device having the features of the additional independent claim.

Advantageous developments are each the subject matter of dependent claims.

In the method according to the invention, for the purpose of treating the underside of a planar substrate with a treatment medium, first of all an underside of the substrate is hydrophobized. Subsequently, a protective liquid film is formed on a top side of the substrate. Then, the treatment medium is brought into contact with the underside of the substrate and in the process the top side is protected from any action of the treatment medium and/or the outgassings thereof by means of the protective liquid film.

As a result of the hydrophobization, in this procedure, after the substrate has been removed from the protective liquid, no protective liquid passes from the top side onto the underside of the substrate. The problem of streaking outlined above and the resulting disadvantages can therefore be avoided. Furthermore, it is possible to prevent treatment medium, as described above, from creeping from the underside onto the top side. This is advantageous in particular in the case of sulfuric-acid-free treatment media. Moreover, as a result of the hydrophobization, a drying step, which would have been necessary before any further process step in the previously known methods, can be dispensed with in many application cases. Furthermore, the method can be conceived as a continuous method and is easy to integrate into already existing continuous installations.

Hydrophobization within the meaning of the present invention exists when the protective liquid wets the hydrophobized surface at a contact angle greater than 60°.

By means of the protective liquid, the top side can basically be protected from the treatment medium per se, which can be present in particular as a liquid or gas, or gas mixture. If a treatment liquid is used, the protective liquid film is preferably used both for protection with respect to treatment liquid passing onto the top side and also for protection with respect to outgassings, passing onto the top side of the substrate, out of the treatment liquid. Such outgassings can arise for example as a result of partial evaporation of the treatment liquid.

Preferably, water, particularly preferably deionized water, is used as the protective liquid. This has proven successful in many application cases and can usually be prepared or disposed of comparatively easily.

Advantageously, a silicon substrate is treated and, for the purpose of hydrophobizing the underside of this silicon substrate, a silicate glass layer, for example a phosphorus silicate glass layer or a boron silicate glass layer, is removed from the underside of the silicon substrate. Such silicate glass layers are frequently used in the production of semiconductor components, in particular in the production of silicon solar cells, and so this allows a procedure that is particularly favorable in terms of effort. In addition, it is possible to use proven techniques for the hydrophobization of the silicon substrate.

In an embodiment variant of the method, for the purpose of forming the protective liquid film, a protective liquid is applied to the top side of the substrate by means of an application device. It is in principle possible to use any application devices that are known per se, for example spray nozzles, as the application device. Preferably, at least one surge pipe is used as the application device.

In an alternative embodiment variant, for the purpose of forming the protective liquid film, the substrate is dipped into the protective liquid and removed from the latter. When the substrate is removed from the protective liquid, the substrate is oriented such that it extends in a substantially horizontally extending plane, such that the desired protective liquid film remains on a top side of the substrate. The fact that the substrate is oriented such that it extends in a substantially horizontally extending plane when it is removed from the protective liquid should be understood as meaning that minor deviations from the horizontal are briefly possible. How long it is possible to deviate from the horizontal and to what precise extent depends on the properties of the materials used, in particular on a viscosity of the protective liquid and adhesive forces between the top side of the substrate and the protective liquid. Complicated application devices such as spray nozzles, surge pipes or the like are not necessary in this embodiment variant. It also does not require any metering devices and measuring devices, which would be necessary in order to determine the position of the substrate and to ensure precise metering of protective liquid onto the top side of the substrate at the correct time and in this way to limit the quantity of protective liquid running down from the top side of the substrate.

Preferably, before the substrate is dipped into the protective liquid, the edges of the substrate are likewise, preferably completely, hydrophobized. This takes place advantageously in a common method step with the hydrophobization of the underside of the substrate. This means that the underside and the edges of the substrate are hydrophobized simultaneously in a single method step. By means of the hydrophobized edges, the risk of creeping of treatment liquid onto the top side of the substrate, which can occur in principle when the treatment liquid comes into contact with non-hydrophobized edge parts for any reason, can be reduced further.

The underside of the substrate can advantageously be hydrophobized by means of one-sided, wet-chemical etching. In this connection, one-sided means that no etching solution that is used for the wet-chemical etching is introduced onto the top side. In this way, it is possible to use installations which have already proven successful in a different context in practice. Moreover, in this method variant, the edges can likewise be fully or partially hydrophobized in a favorable manner in terms of effort in the same method step.

Particularly preferably, for the purpose of hydrophobizing the underside of the substrate, the substrate is wetted from beneath with an etching liquid. This allows hydrophobization on an industrial scale, inter alia in continuous installations. In particular, the substrate can be guided through an etching tank in a manner floating as it were on the surface of the etching liquid such that the etching liquid wets the underside of the substrate. In particular, however, the etching liquid can also be introduced onto the underside of the substrate in any other manner, for example by means of transporting rollers which absorb the etching liquid and pass it on to the substrates transported thereon. In this method variant, the edges can likewise be advantageously fully or partially hydrophobized.

Advantageously, after the wet-chemical etching, carried out for the purpose of hydrophobization, the substrate is rinsed. In one method variant, this takes place in that a rinsing liquid is applied to the substrate, for example by means of a surge pipe or some other application device. The quantity of rinsing liquid applied to the substrate is in this case chosen such that at least half, preferably at least 70%, and particularly preferably at least 80%, of the applied quantity of rinsing liquid drips off the substrate and rinses off any residual etching liquid. The rinsing liquid ultimately remaining on the top side is used subsequently as a protective liquid film, and so no additional method steps are required for the formation thereof.

In an alternative method variant, for the purpose of rinsing, the substrate is dipped into a rinsing liquid and this rinsing liquid is simultaneously used as the protective liquid. Removal of the substrate from the rinsing liquid then simultaneously represents the removal of the substrate from the protective liquid. When it is removed from the protective liquid, the substrate is oriented in the above-described manner such that it extends in a substantially horizontally extending plane, such that the protective liquid film remains on the top side of the substrate. In this way, the method can be realized particularly quickly and in a favorable manner in terms of effort.

In principle, any liquid that is suitable for the particular application case can be used as the rinsing liquid. Preferably, water is used, and particularly preferably deionized water in the production of semiconductor components such as solar cells, for example, for reasons of contamination.

In a method variant that has proven successful, an etching medium is used as the treatment medium and the underside of the substrate is etched by means of this etching medium. During this etching, material can be removed. For example, it can be polishing etching. In particular, the underside of a silicon solar cell substrate can be etched. This method variant has therefore proven successful in particular in the production of novel, highly efficient solar cells with passivated emitters and passivated rear contacts.

Advantageously, for the purpose of forming the protective liquid film, the protective liquid is applied to the top side of the substrate several times. This means that the protective liquid is applied in several, temporally offset application operations. For example, a second application operation begins after a first application operation has already started or after the first application operation has ended. Preferably, the second application operation begins after the first application operation has ended.

It has been shown that, by means of the application of the protective liquid several times, the protective liquid can be distributed better on the top side of the substrate. In particular, it has been shown that the protective liquid can pass better into corners of the substrate and onto peripheral regions of the substrate in various application cases. The risk of islands of protective liquid forming on the top side of the substrate, which leave parts of the top side of the substrate uncovered, is reduced or even avoided. Depending on the application case, the quantity of protective liquid applied to the top side of the substrate for the purpose of forming the protective liquid film can therefore be reduced overall without this being associated with an increased risk of subregions of the top side of the substrate not being covered with the protective liquid film. In particular in the above-described method variant in which the substrate is dipped into a protective liquid and is oriented when it is removed such that the protective liquid film remains on the top side of the substrate, the described application of the protective liquid several times can additionally serve to reinforce or complete the protective liquid film. This can be advantageous in individual application cases, for example when, in an unfavorable procedure, too much protective liquid runs off the top side of the substrate during the removal of the substrate from the protective liquid or too much protective liquid evaporates out of the protective liquid film during the further procedure. Additionally, it should be noted that the above-described horizontal removal of the substrate from the protective liquid and the associated remaining of a protective liquid film on the top side of the substrate represents an application of protective liquid to the top side of the substrate.

The device according to the invention has a preconditioning tank which contains a liquid by means of which the substrates to be treated can be hydrophobized. Provided downstream of the preconditioning tank in a transporting direction of the substrates is a rinsing tank. The latter can contain a rinsing medium or be provided to catch rinsing liquid dripping off. Furthermore, a treatment tank arranged downstream of the rinsing tank in the transporting direction of the substrates is provided, which contains a treatment liquid. Provided in the preconditioning tank are transporting rollers which are suitable for transporting the substrates through the preconditioning tank. These transporting rollers are embodied predominantly, preferably exclusively, as plateau-free structure rollers.

In the present case, plateau-free structure rollers should be understood as being transporting rollers which have on their surface annular recesses, known as grooves, which circumferentially enclose the transporting roller. These recesses are arranged on the transporting roller in a manner immediately adjoining one another. At those locations at which the recesses adjoin one another, the walls of adjacent recesses butt against one another and form raised regions on the transporting roller surface. In the case of plateau-free structure rollers, the adjacent recesses are arranged in a manner closely adjoining one another such that these raised regions no longer represent plateaus, but rather can be considered points of some kind. By means of plateau-free structure rollers, the underside of the substrate can be wetted uniformly. Bubbles that arise during the etching operation are distributed homogeneously over the underside of the substrate and are repeatedly wiped off. This allows a more homogeneous etching result, especially at high etching rates. Furthermore, it has been shown that, when plateau-free structure rollers are used, the risk of a transporting roller delivering the hydrophobizing liquid or some other treatment liquid to the top side of the substrate at the moment at which this substrate leaves this transporting roller is considerably reduced compared with full rollers. The use of plateau-free structure rollers in the preconditioning tank therefore allows a further reduction in the risk of damage to the top side of the substrate.

Advantageously, predominantly O-ring rollers are provided as transporting rollers in the rinsing tank in order to transport the substrates, said O-ring rollers each having a shaft element and a plurality of O-ring receptacles spaced apart from one another in the longitudinal direction of the shaft element. An O-ring is arranged in each of said O-ring receptacles, said O-ring circumferentially surrounding the shaft element and the respective O-ring receptacle. In a poorer quality embodiment, formations on the shaft element can be provided instead of O-ring receptacles and O-rings arranged therein.

Preferably, exclusively the above-described O-ring rollers are arranged as transporting rollers in the rinsing tank. In this way, the contact area between the transporting roller and substrate transported thereon is minimized. As a result, hydrophobizing liquid, still adhering to the substrate, from the preconditioning tank can be rinsed away better. O-ring rollers have a very low inclination to deliver liquid onto the top sides of the substrates when the substrate leaves the O-ring roller. Nevertheless, it is not advantageous to use them in the preconditioning tank or the treatment tank since they leave behind roller traces which counteract the aim of a homogeneous etching result. As has been found, the advantages of the extremely low risk of damage to the substrate top sides by liquid scooped onto the top side prevail in the rinsing tank, however.

Advantageously, predominantly, preferably exclusively, plateau-free structure rollers are provided as transporting rollers in the treatment tank in order to transport the substrates through the treatment tank. The effects, already described in connection with the preconditioning tank, of the plateau-free structure rollers likewise have an advantageous impact in the treatment tank and allow a further reduction in the risk of damage to the top side of the treated substrates.

An etching solution containing hydrofluoric acid can be provided as the hydrophobizing liquid in the preconditioning tank. This has proven successful in particular in the removal of silicate glass layers from silicon substrates.

An etching solution which contains hydrofluoric acid and an oxidizing agent, preferably nitric acid or hydrogen peroxide, can be provided as the treatment liquid. In another configuration variant, an etching solution which, in addition to the abovementioned hydrofluoric acid and the abovementioned oxidizing agent, additionally contains an additive, preferably sulfuric acid, can be provided as the treatment liquid. Both variants have proven successful in particular in the treatment of silicon substrates.

Advantageously, a plurality of application devices are provided, by means of which a protective liquid is able to be applied to a top side of the substrates. This plurality of application devices are arranged in an offset manner with respect to one another in the transporting direction of the substrates. This makes it possible, as described above, to apply protective liquid to the top side of the substrates several times.

Preferably, at least one of the plurality of application devices is arranged above the rinsing tank. An application device can be formed for example of a surge pipe or the like or of transporting rollers by means of which the substrates are transported through at least a part of the rinsing tank in a manner dipped fully into a rinsing liquid arranged in the rinsing tank.

It has proven advantageous for at least one of the plurality of application devices to be arranged downstream of the rinsing tank in the transporting direction of the substrates. In this way, losses of protective liquid from the top side of the substrates that have taken place in the meantime, for example as a result of evaporation effects, can be compensated easily.

Advantageously, at least one of the plurality of application devices is arranged above the treatment tank. In this way, evaporation losses or shortfalls of protective liquid on the top side of the substrates can be compensated during the action of the treatment liquid. The risk of shortfalls or evaporation losses of protective liquid arising again is minimized in this way.

The invention is explained in more detail in the following text with reference to figures. Where expedient, elements with the same action are provided with the same reference signs therein. The invention is not limited to the exemplary embodiments illustrated in the figures—not even with regard to functional features. The above description and the following description of the figures contain numerous features which are reproduced in the dependent claims, in some cases combined into groups. However, a person skilled in the art will also consider these features and also all of the other features disclosed above and in the following description of the figures individually and combine them into appropriate further combinations. In particular, these features are each able to be combined individually and in any desired suitable combination with the method and/or the device of the independent claims. In the figures:

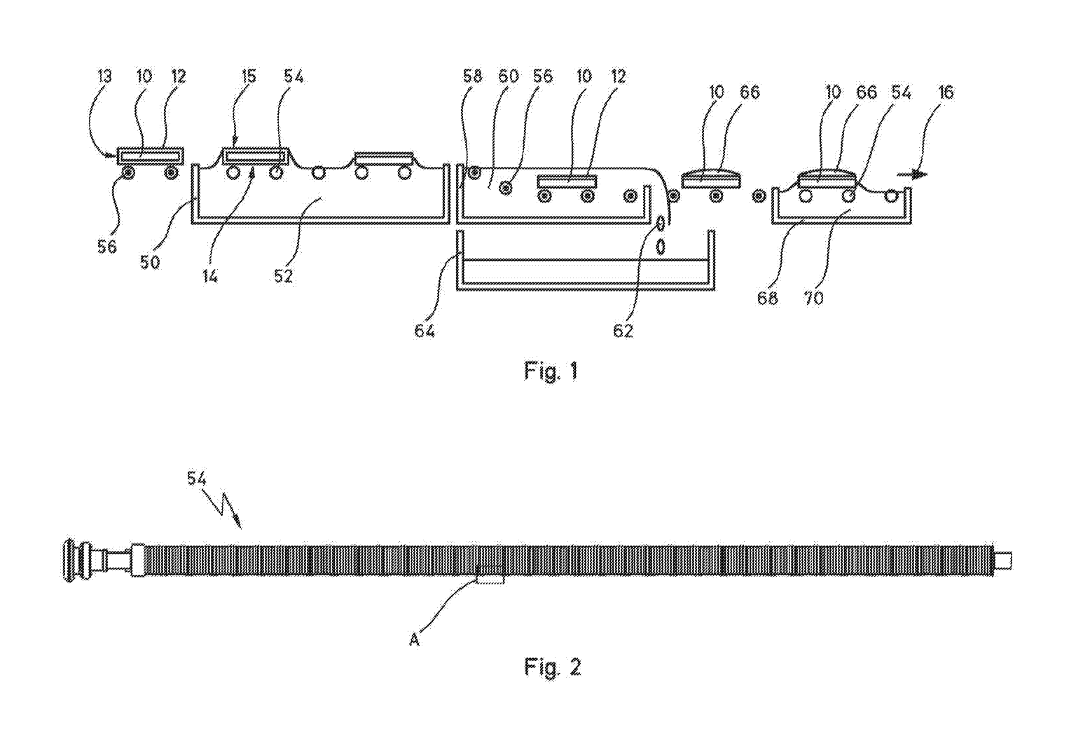

FIG. 1 shows a first exemplary embodiment of the method according to the invention and of the device according to the invention in a schematic illustration

FIG. 2 shows a side view of a plateau-free structure roller from FIG. 1

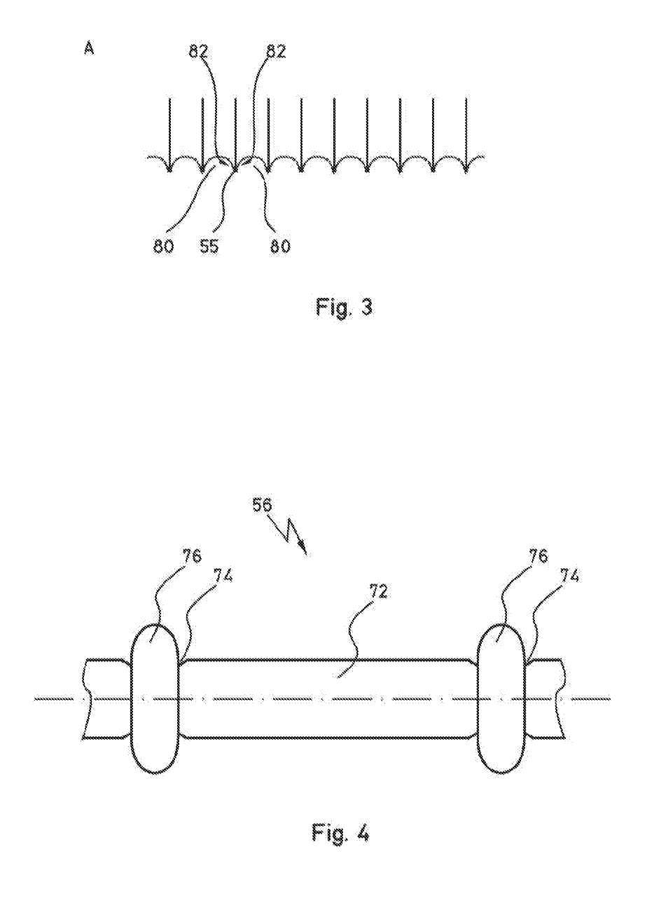

FIG. 3 shows a detail illustration of a subregion A from FIG. 2

FIG. 4 shows a schematic illustration of an O-ring roller

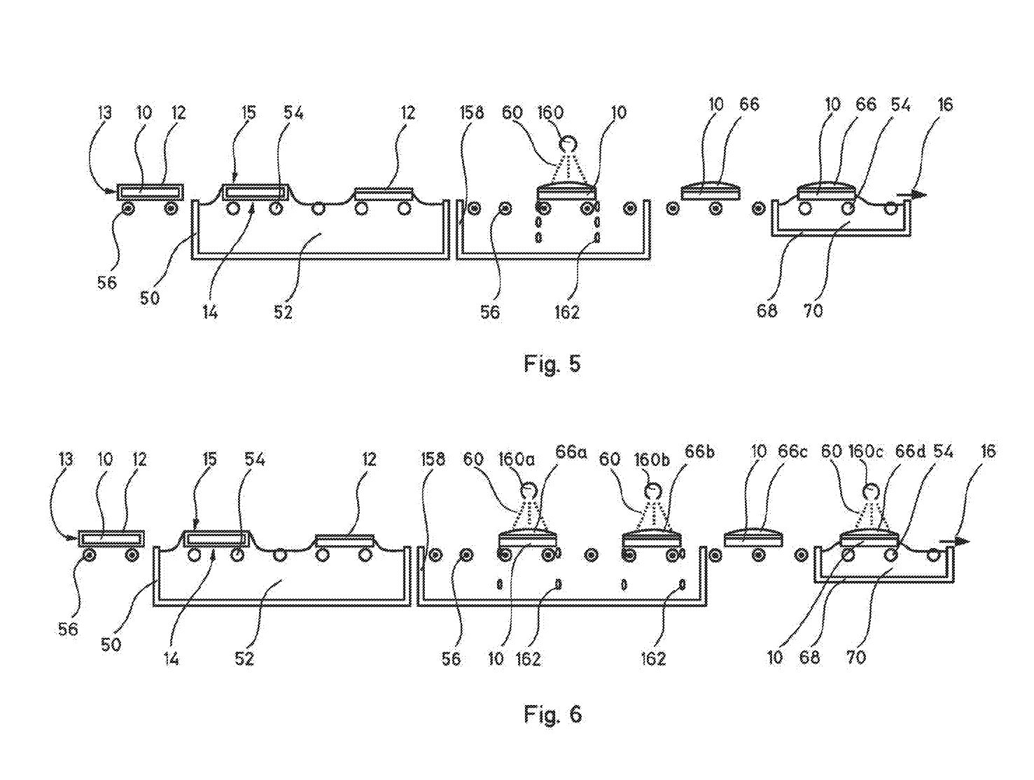

FIG. 5 shows a second exemplary embodiment of the method according to the invention and of the device according to the invention in a schematic illustration

FIG. 6 shows a third exemplary embodiment of the method according to the invention and of the device according to the invention in a schematic illustration.

FIG. 1 illustrates a schematic illustration of an exemplary embodiment of the method according to the invention and of the device according to the invention. In this exemplary embodiment, a silicon substrate 10, which is provided on its entire surface with a phosphorus silicate glass layer 12, for example as a result of phosphorus diffusion, is transported in a transporting direction 16 through a succession of different tanks by means of transporting rollers. First of all, an underside 14 and the edges 13 of the substrate 10 are hydrophobized in a preconditioning tank 50. For this purpose, the underside 14 of the substrate 10 is wetted from beneath with a hydrophobizing liquid 52, in the present exemplary embodiment with an etching solution containing hydrofluoric acid. Exclusively plateau-free structure rollers 54 are provided as transporting rollers in the preconditioning tank, said plateau-free structure rollers 54 allowing homogeneous etching. As a result, the phosphorus silicate glass layer 12 is removed uniformly from the underside 14 and from the edges 13.

A side view of the plateau-free structure rollers 54 used in the exemplary embodiment in FIG. 1 can be found in FIG. 2. An enlarged illustration of the subregion A is reproduced in FIG. 3. In the latter, deeply grooved recesses 80 are discernible, which are arranged on the structure roller 54 in a manner immediately adjoining one another and form raised regions. Walls 82 of two adjacent recesses 80 are in this case arranged in a manner closely adjoining one another such that these raised regions do not exhibit a plateau but rather the shape of a point 55. As explained above, the plateau-free structure rollers 54 allow homogeneous etching of the underside 14 of the substrate 10 in the preconditioning tank 50 with a comparatively low risk of undesired local hydrophobizing of the top side 15 as a result of hydrophobizing liquid 52 being scooped onto the top side 15.

In the further procedure, the substrate 10 is transported into a rinsing tank 58 which contains deionized water 60 as rinsing medium. There, it is dipped into the deionized water 60 that serves as rinsing liquid. In this case, the deionized water 60 is simultaneously used as protective liquid. The substrate 10 is transported in the rinsing tank 58 by means of O-ring rollers 56 which minimize the bearing surface for the substrate and in this way allow an efficient rinsing operation. Water 62 overflowing out of the rinsing tank 58 is collected in an overflow tank 64.

FIG. 4 shows a schematic illustration of a portion of the O-ring roller 56. The O-ring roller 56 has a shaft element 72 and O-ring receptacles which are spaced apart from one another in the longitudinal direction of the shaft element 72 and are embodied as recesses 74 in the shaft element 72 in the case of the present example, an O-ring 76 being arranged in each of said recesses 74. The portion of the O-ring roller 56 that is illustrated in FIG. 4 has two O-rings 76. This number is sufficient in principle for transporting the planar substrate 10. If necessary, for example in the case of larger or fragile substrates, a larger number of O-rings can be provided.

If the substrate 10 is transported onward in the transporting direction 16 by means of the O-ring shafts 56, it is removed from the rinsing tank 58 in this way. In this case, the substrate 10 extends in a horizontally extending plane. The O-ring rollers 56 are oriented in a corresponding manner for this purpose. The previously hydrophobized edges 13 and the hydrophobized underside 14 are free of deionized water 60 after the substrate 10 has been removed from the rinsing tank 58. By contrast, a protective liquid film 66 of deionized water 60 remains on the top side 15. The hydrophilic phosphorus silicate glass layer 12 that remains on the top side 15 of the substrate 10 additionally favors the formation of the protective liquid film 66, wherein hydrophilicity should be understood in the present sense as meaning a contact angle between the surface and wetting liquid of less than 15°. The hydrophilicity of the top side 15 also additionally counteracts any running off of deionized water from the protective liquid film 66.

Subsequently, the substrate 10 is transported into a treatment tank 60 which contains an etching solution 70. In the present exemplary embodiment, an etching solution 70 containing hydrofluoric acid and nitric acid is provided as the etching solution. Alternatively, it is possible, inter alia, to use an etching solution which contains sulfuric acid in addition to hydrofluoric acid and nitric acid. While the substrate is transported through the treatment tank 68 by means of the plateau-free structure rollers 54, the etching solution 70 is brought into contact with and etches the underside 14 of the substrate. The top side 15 of the substrate 10 is, by contrast, protected by the protective liquid film 66 against etching solution 70 passing onto the top side 15 and against any effect of outgassings from the etching solution 70, in particular from etching vapors. The underside 14 is etched without the sensitive top side 15 of the substrate 10 being impaired. Any running off of deionized water from the protective liquid film 66 or creeping of etching solution 70 onto the top side 15 of the substrate 10 is prevented. No streaking occurs on the underside 14 of the substrate 10 and the etching solution 70 is not contaminated or diluted by parts of the protective liquid film 66 running off the top side 15 of the substrate 10. The above-described advantages of the plateau-free structure rollers 54 also have a positive effect in the treatment tank, and so the risk of damage to the top side 15 of the substrate 10 is further reduced by the exclusive use of plateau-free structure rollers 54.

A residence time of the substrates 10 in the preconditioning tank 50 should be chosen such that the phosphorus silicate glass layer 12 is reliably removed from the underside 14 of the substrate 10. The length of the preconditioning tank 50 should optionally be adapted in a corresponding manner. However, the substrates cannot be exposed to the hydrophobizing liquid 52 for any desired length of time. Otherwise, it is possible for the hydrophobizing liquid 52 to creep onto the top side 15 of the substrate 10 and to considerably damage the latter or layers located therebeneath. The residence time of the substrates in the preconditioning tank 50, and the length of this tank, should therefore be chosen accordingly. Otherwise, depending on the thickness of the phosphorus silicate glass layer 12 or depending on material properties and thicknesses of other layers to be removed, it may be advantageous to use suitable transporting rollers. For example, plateau-free structure rollers that are grooved more or less deeply can be used.

FIG. 5 illustrates a schematic illustration of a second exemplary embodiment of the method according to the invention and of the device according to the invention. This differs from the first exemplary embodiment in FIG. 1 in that, instead of the rinsing tank 58, a rinsing tank 158 is provided which collects rinsing liquid. For the purposes of rinsing, a surge pipe 160 is provided, by means of which the deionized water 60 used as rinsing liquid is applied to the top side 15 of the silicon substrates. The deionized water 60 is applied in such a quantity that water 162 that drips off over the edges 13 of the silicon substrates 10 rinses the silicon substrates. Once the silicon substrate 10 has passed through under the surge pipe 160, a film of deionized water remains on the top side 15 of the silicon substrates 10, said film being used as protective liquid film 66. If it is not necessary to rinse the substrates, the deionized water, or some other suitable protective liquid, can in principle be applied in a metered manner to the top side 15 of the silicon substrates 10 by means of the surge pipe 160 such that the protective liquid film 66 is formed but only as little protective liquid as possible runs over the edges 13 of the silicon substrates 10 and drips into the rinsing tank 158.

FIG. 6 illustrates a schematic illustration of a third exemplary embodiment of the method according to the invention and of the device according to the invention. This differs from the second exemplary embodiment illustrated in FIG. 5, inter alia, in that, in addition to a surge pipe 160a, a further surge pipe 160b is provided, which is arranged downstream of the surge pipe 160a in the transporting direction 16 of the substrates 10. By means of these surge pipes 160a and 160b, the deionized water 60 is again applied as protective liquid to the substrates 10. The surge pipes 160a, 160b thus serve as application devices. Since they are arranged in an offset manner with respect to one another in the transporting direction 16 of the substrates, the deionized water 60 is applied as protective liquid several times to the top side 15 of the substrates 10 by means of these surge pipes 160a, 160b.

The deionized water 60 applied to the top side 15 of the substrates 10 by means of the surge pipe 160a forms a protective liquid film 66a which, in the particular application case, possibly does not yet completely cover the top side 15 or does not yet have a sufficient thickness. In particular, the protective liquid film 66a can have formed islands such that parts of the top side 15 are not or not sufficiently covered with protective liquid. As a result of the second application of deionized water 60 as protective liquid by means of the surge pipe 160b, imperfections in the protective liquid film 66a can be compensated, such that a protective liquid film 66b completely covering the top side 15 of the substrates 10 is present. If the protective liquid film 66a merely does not have a sufficient thickness, the application of the deionized water 60 by means of the surge pipe 160b brings about a thicker protective liquid film 66b.

As described above, as a result of the protective liquid, in the present case the deionized water 60, being applied several times, a better distribution of the protective liquid in corners of the substrates 10 and the peripheries of the substrates 10 can be brought about. After the rinsing tank 158 has been passed through, in the exemplary embodiment in FIG. 6, a protective liquid film 66c is thus present which completely and homogeneously covers the top side 15 of the substrates 10. Depending on the application case, the application of deionized water 60, or of protective liquid, several times can reduce the total quantity of overflowing water 162. This allows a reduction in the procedural effort, in particular when protective liquids other than water are used.

In the exemplary embodiment in FIG. 6, a further surge pipe 160c for applying the deionized water 60 to the top side 15 of the substrates 10 is arranged above the treatment tank 68, and thus downstream of the rinsing tank 158 in the transporting direction 16 of the substrates 10. The surge pipe 160c is, like the surge pipes 160a and 160b, provided to apply deionized water 60 as protective liquid to the top side 15 of the substrates 10. In this way, losses of deionized water 60 which the protective liquid film 66c has suffered on the way to the treatment tank 68, for example on account of evaporation, can be compensated, and so the top side 15 of the substrates 10 is protected from any action of the treatment medium 70 and/or outgassings thereof via the treatment tank 68 by means of an ideal protective liquid film 66d.

In the exemplary embodiment in FIG. 6, three application devices for protective liquid are provided by the surge pipes 160a, 160b, 160c. Depending on the requirements of the individual application case, one of these application devices, preferably the surge pipe 160b or the surge pipe 160c, can be dispensed with. With the remaining two surge pipes, a plurality of application devices that are arranged in an offset manner with respect to one another in the transporting direction 16 of the substrates 10 are still present, said application devices allowing protective liquid, in the present case deionized water 60, to be applied several times for the purpose of forming the protective liquid film. In an application case in which the protective liquid can be applied in a metered manner such that, when protective liquid is applied to the top side 15 of the substrate via the treatment tank 68, virtually no protective liquid overflows and thus also does not pass into the etching solution 70, it has proven particularly advantageous to keep the surge pipe 160c, or more generally an application device above the treatment tank 68.

The concept, illustrated in the exemplary embodiment in FIG. 6, of a plurality of application devices arranged in an offset manner with respect to one another in the transporting direction 16 of the substrates 10 can be transferred readily to the exemplary embodiment in FIG. 1. For this purpose, one or more application devices would need to be provided downstream of the rinsing tank in the transporting direction 16 of the substrates in the exemplary embodiment in FIG. 1, by means of which application devices deionized water can again be applied as protective liquid to the top side 15 of the substrates. For example, the surge pipes 160b or 160c known from FIG. 6 or the like could be used. In particular, such a further application device could be arranged above the treatment tank 68 in FIG. 1.

The invention has been illustrated and described in more detail by way of the exemplary embodiments illustrated and explained. Nevertheless, the invention is not limited to or by the examples disclosed. Other variants can be derived from these exemplary embodiments by a person skilled in the art without deviating from the concept underlying the invention.

### LIST OF REFERENCE SIGNS

10 Silicon substrate

12 Phosphorus silicate glass layer

13 Edge

14 Underside

15 Top side

16 Transporting direction

50 Preconditioning tank

52 Hydrophobizing liquid

54 Structure roller

55 Point

56 O-ring roller

58 Rinsing tank

60 Deionized water

62 Overflowing water

64 Overflow tank

66 Protective liquid film

66a Protective liquid film

66b Protective liquid film

66c Protective liquid film

66d Protective liquid film

68 Treatment tank

70 Etching solution

72 Shaft element

74 Recess

76 O-ring

80 Recess

82 Wall

158 Rinsing tank

160 Surge pipe

160a Surge pipe

160b Surge pipe

160c Surge pipe

162 Overflowing water

1-19. (canceled)

20. A method for treating an underside of a planar substrate with a treatment medium, the method comprising the following steps:
hydrophobizing the underside of the substrate;
subsequently forming a protective liquid film on a top side of the substrate; and
subsequently bringing the treatment medium into contact with the underside of the substrate while using the protective liquid film to protect the top side of the substrate from at least one of action or outgassing of the treatment medium.

21. The method according to claim 20, which further comprises:
providing a silicon substrate as the substrate to be treated; and
carrying out the step of hydrophobizing the underside of the silicon substrate by removing a silicate glass layer from the underside of the silicon substrate.

22. The method according to claim 20, which further comprises:
carrying out the step of forming the protective liquid film by dipping the substrate into a protective liquid and removing the substrate from the protective liquid; and
orienting the substrate to extend in a substantially horizontally extending plane upon removing the substrate from the protective liquid, causing the protective liquid film to remain on the top side of the substrate.

23. The method according to claim 20, which further comprises before carrying out the step of forming the protective liquid film, hydrophobizing edges of the substrate together with or separately from the step of hydrophobizing the underside of the substrate.

24. The method according to claim 20, which further comprises carrying out the step of hydrophobizing the underside of the substrate by using one-sided, wet-chemical etching.

25. The method according to claim 24, which further comprises carrying out the step of hydrophobizing the underside of the substrate by wetting the substrate from below with an etching liquid.

26. The method according to claim 24, which further comprises:
after carrying out the step of hydrophobizing the underside of the substrate by wet-chemical etching, applying a rinsing liquid to the substrate for rinsing;
choosing a quantity of the rinsing liquid applied to the substrate to cause at least half of the applied quantity of rinsing liquid to drip off the substrate; and
using rinsing liquid remaining on the top side of the substrate as the protective liquid film.

27. The method according to claim 22, which further comprises:
carrying out the step of hydrophobizing the underside of the substrate by using one-sided, wet-chemical etching; and
subsequently dipping the substrate into a rinsing liquid for rinsing and simultaneously using the rinsing liquid as the protective liquid, causing removal of the substrate from the rinsing liquid to simultaneously represent the removal of the substrate from the protective liquid.

28. The method according to claim 26, which further comprises using water as the rinsing liquid.

29. The method according to claim 26, which further comprises using deionized water as the rinsing liquid.

30. The method according to claim 20, which further comprises using an etching medium as the treatment medium, and etching the underside of the substrate by using the etching medium.

31. The method according to claim 20, which further comprises carrying out the step of forming the protective liquid film by applying the protective liquid to the top side of the substrate a multiplicity of times.

32. A device for treating undersides of planar substrates with a treatment medium, the device comprising:
a preconditioning tank containing a liquid for hydrophobizing the undersides of the substrates to be treated;
a rinsing tank disposed downstream of said preconditioning tank in a transporting direction of the substrates for forming a protective liquid film on top sides of the substrates;
a treatment tank disposed downstream of said rinsing tank in said transporting direction of the substrates, said treatment tank containing a treatment liquid to be brought into contact with the undersides of the substrates while protecting the top sides of the substrates from at least one of action or outgassing of said treatment medium; and
transporting rollers disposed in said preconditioning tank for transporting the substrates through said preconditioning tank, a majority or all of said transporting rollers being plateau-free structure rollers.

33. The device according to claim 32, which further comprises:
transporting rollers disposed in said rinsing tank for transporting the substrates through said rinsing tank, a majority or all of said transporting rollers being O-ring rollers;
said O-ring rollers each having a shaft element with a longitudinal direction and a plurality of O-ring receptacles spaced apart from one another in said longitudinal direction; and
said O-ring rollers having O-rings each being disposed in a respective one of said O-ring receptacles, and said O-rings each circumferentially surrounding one of said shaft elements and a respective one of said O-ring receptacles.

34. The device according to claim 32, which further comprises transporting rollers disposed in said treatment tank for transporting the substrates through said treatment tank, a majority or all of said transporting rollers being plateau-free structure rollers.

35. The device according to claim 32, wherein:
said liquid for hydrophobizing the undersides of the substrates is an etching solution containing hydrofluoric acid; and
said treatment liquid is a further etching solution containing hydrofluoric acid and an oxidizing agent.

36. The device according to claim 35, wherein said oxidizing agent is nitric acid or hydrogen peroxide.

37. The device according to claim 32, which further comprises a plurality of application devices for applying a protective liquid to the top sides of the substrates, said plurality of application devices being mutually offset in said transporting direction of the substrates.

38. The device according to claim 37, wherein at least one of said plurality of application devices is disposed above said rinsing tank.

39. The device according to claim 38, wherein at least one of said plurality of application devices is disposed downstream of said rinsing tank in said transporting direction of the substrates.

40. The device according to claim 39, wherein at least one of said plurality of application devices is disposed above said treatment tank.
